(19) United States
(12) Patent Application Publication
(10) Pub. No.: US 2024/0186318 A1
(43) Pub. Date: Jun. 6, 2024

(54) INTEGRATED CIRCUIT COMPRISING A CAPACITIVE TRANSISTOR

(71) Applicant: STMicroelectronics (Rousset) SAS, Rousset (FR)

(72) Inventors: Christian RIVERO, Rousset (FR); Joel METZ, Gardanne (FR); Brice ARRAZAT, Bouc-Bel-Air (FR)

(73) Assignee: STMicroelectronics (Rousset) SAS, Rousset (FR)

(21) Appl. No.: 18/526,384

(22) Filed: Dec. 1, 2023

(30) Foreign Application Priority Data
Dec. 2, 2022 (FR) 2212707

(51) Int. Cl. H01L 27/06; H01L 29/423; H01L 29/66; H01L 29/94

(52) U.S. Cl. CPC H01L 27/0629; H01L 29/42336; H01L 29/66181; H01L 29/945

(57) ABSTRACT

An integrated circuit includes a capacitive transistor supported by a semiconductor substrate. The capacitive transistor includes: a drain and a source formed in the semiconductor substrate; a gate having a first portion extending in depth in the semiconductor substrate, and a second portion prolonging said first portion and extending over the semiconductor substrate; and a dielectric layer extending between the gate and the semiconductor substrate.

### PRIORITY CLAIM

This application claims the priority benefit of French Application for Patent No. 2212707, filed on Dec. 2, 2022, the content of which is hereby incorporated by reference in its entirety to the maximum extent allowable by law.

### TECHNICAL FIELD

Embodiments and implementations relate to integrated circuits and, in particular, to integrated circuits including transistors used as capacitive elements.

### BACKGROUND

Integrated circuits that include transistors used as capacitive elements are known.

In particular, a capacitive transistor can be used to operate with high voltages, for example voltages comprised between 7 Volts (V) and 15 Volts.

In particular, capacitive transistors may be located in an area of the integrated circuit including the components operating at high voltages. In particular, capacitive transistors may be used in integrated circuits serving as a non-volatile memory, in particular Electrically-Erasable Programmable Read-Only Memory (EEPROM).

In order to serve as a capacitive element, a capacitive transistor has a gate used as a first terminal of the capacitive element, as well as a drain, a source and a semiconductor substrate (“bulk”) connected together so as to be used as a second terminal of the capacitive element.

Capacitive transistors operating with high voltages may occupy a considerable space in the integrated circuit. In particular, planar capacitive transistors suited to operate at high voltage are known. Such capacitive transistors may occupy a surface in the range of 4% of the total surface area of the integrated circuit.

In particular, a dual-gate planar capacitive transistor has a first gate extending over the semiconductor substrate between the drain and the source of this planar capacitive transistor, and a second gate extending over this first gate and over the semiconductor substrate between the drain and the source of the planar capacitive transistor. The first gate is electrically connected to the second gate.

The effective length of the planar transistor is then defined by the distance over which the first gate extends over the semiconductor substrate.

Such a planar capacitive transistor has a low surface capacitance because of the surface area over which its first gate extends over the semiconductor substrate. For example, such a planar capacitive transistor may have a surface capacitance in the range of 2 femtofarads per square micrometer.

Because of the foregoing, such a planar capacitive transistor needs to extend over a large area of the semiconductor substrate to increase its capacitance. The use of such planar capacitive transistors thus requires providing for large dimensions for the area of the integrated circuit comprising the components used for high-voltage operation. Hence, an integrated circuit comprising such planar capacitive transistors is bulky.

There is accordingly a need to provide an integrated circuit including at least one capacitive transistor capable of operating at high voltage and having reduced dimensions in order to reduce the bulk of the integrated circuit.

### SUMMARY

According to one aspect, an integrated circuit is provided comprising a semiconductor substrate and at least one capacitive transistor including: a drain and a source disposed in the semiconductor substrate; a gate having a first portion extending in depth in the semiconductor substrate, and a second portion prolonging from (i.e., which is a unitary extension of) said first portion and extending over the semiconductor substrate; and a dielectric layer extending between the gate and the semiconductor substrate.

Thus, the capacitive transistor is configured to operate as a capacitive element. In particular, the gate of said at least one capacitive transistor is used as a first terminal of the capacitive element. Furthermore, the drain, the source and the semiconductor substrate (“bulk”) are connected together, in particular by a metal, so as to be used as a second terminal of the capacitive element. The gate is formed by a monolithic layer having said first portion and said second portion. Hence, the first portion of the gate and the second portion of the gate are continuous.

More particularly, the capacitive transistor has a surface capacitive value which depends on the length over which its first portion extends in depth in the semiconductor substrate. Thus, the deeper the first portion of the gate extends, the more its surface capacitive value increases.

Because the surface capacitive value of such a capacitive transistor is greater, it is possible to reduce the size of the capacitive transistors so as to reduce the area of the integrated circuit used for high-voltage operation.

For example, the use of such capacitive transistors instead of planar capacitive transistors allows reducing by 30% to 50% the surface of an area of the integrated circuit for high voltage operation. Thus, it is possible to manufacture more integrated circuits starting from the same semiconductor disk (“wafer”), and therefore reduce the manufacturing cost of each integrated circuit.

In an advantageous embodiment, the first portion of the gate of said at least one capacitive transistor extends in depth in the substrate over a distance comprised between 300 nanometers (nm) and 1,200 nanometers.

This first portion may extend in an active area of the substrate and further extend beyond the active area in an isolation area formed in the substrate around said active area.

In particular, in order to avoid coupling with the elements of the integrated circuit located nearby, it is preferably to have first portions having longitudinal parts extending at different depths depending on whether these parts extend in the active area or in the isolation area. For example, the part of the first portion that extends in the active area may extend in depth in the substrate over a distance comprised between 700 nm and 900 nm. Each part of the first portion that extends in the isolation area may extend in depth in the substrate over a distance comprised between 900 nm and 1,200 nm.

Advantageously, the first portion of the gate of said at least one capacitive transistor has a width comprised between 100 nm and 300 nm.

Preferably, the second portion of the gate of said at least one capacitive transistor has a thickness comprised between 80 nm and 200 nm.

In an advantageous embodiment, the dielectric layer of said at least one capacitive transistor is an oxide layer.

Preferably, the dielectric layer of said at least one capacitive transistor has a thickness comprised between 80 Ångström (i.e., 8 nm), and 400 Ångström (i.e., 40 nm). Such a dielectric layer is configured to withstand high voltages, for example comprised between 7V and 15V. Advantageously, the integrated circuit further comprises a first contact connected to the second portion of the gate of said at least one capacitive transistor and a second contact connected to the source or to the drain of said at least one capacitive transistor. Thus, such a capacitive transistor has the advantage of enabling a positioning of the first contact directly over its gate, and not over a shallow isolation trench outside an active area of said at least one capacitive transistor.

Advantageously, the gate of said at least one capacitive transistor is made of polysilicon, and in particular N-doped, for example by doping in situ during the deposition or by implantation using a mask.

In an advantageous embodiment, the integrated circuit comprises several capacitive transistors, the second portion of the gate of these capacitive transistors being common for these capacitive transistors.

Preferably, the first portions of the gates of the capacitive transistors extend in depth in the substrate and are spaced apart from each other by a distance comprised between 0.1 μm and 1.5 μm.

In an advantageous embodiment, said at least one capacitive transistor further comprises two dielectric strips extending: either completely over lateral borders of the second portion of its gate, or over the lateral borders of the second portion of its gate and over the semiconductor substrate.

These two dielectric strips may be made of an oxide-nitride-oxide (“ONO”) material layer. These two dielectric strips allow avoiding electrical short-circuits.

Advantageously, the integrated circuit further comprises at least one planar transistor including: a drain and a source disposed in the semiconductor substrate; a floating gate extending over the semiconductor substrate and being of the same nature as the gate of said at least one capacitive transistor; a control gate extending over the floating gate and over the semiconductor substrate between the drain and the source; a first dielectric layer extending between the floating gate and the semiconductor substrate; and a second dielectric layer extending between the floating gate and the control gate.

According to another aspect, a method for manufacturing an integrated circuit is provided comprising manufacturing at least one capacitive transistor over a semiconductor substrate, said manufacture of said at least one capacitive transistor including: forming a drain and a source of said at least one capacitive transistor in the semiconductor substrate; forming a gate of said at least one transistor comprising etching a trench in the semiconductor substrate then depositing an electrically-conductive layer so that the gate has: a first portion of said conductive layer extending in depth in said trench etched in the semiconductor substrate, and a second portion of said conductive layer prolonging from (i.e., which is a unitary extension of) said first portion and extending over the semiconductor substrate; and forming a dielectric layer in said trench so that the dielectric layer extends between the gate and the semiconductor substrate.

In an advantageous implementation, the trench is formed so that the first portion of the gate of said at least one capacitive transistor extends in depth in the substrate over a distance comprised between 300 nm and 1,200 nm.

Advantageously, the trench is formed so that the first portion of the gate of said at least one capacitive transistor has a width comprised between 100 nm and 300 nm.

Preferably, the deposition of the electrically-conductive layer is carried out so that the second portion of the gate of said at least one capacitive transistor has a thickness comprised between 80 nm and 200 nm.

In an advantageous implementation, the dielectric layer of said at least one capacitive transistor is an oxide layer.

Advantageously, the dielectric layer of said at least one capacitive transistor has a thickness comprised between 80 Ångström (i.e., 8 nm) and 400 Ångström (i.e., 40 nm).

Preferably, the method further comprises forming a first contact connected to the second portion of the gate of said at least one capacitive transistor and forming a second contact connected to the source or to the drain of said at least one capacitive transistor.

Advantageously, the gate of said at least one capacitive transistor is made of polysilicon, and in particular N-doped, for example by doping in situ during the deposition or by implantation using a mask.

In an advantageous implementation, the method comprises forming several capacitive transistors, the second portion of the gate of these capacitive transistors then being common for these capacitive transistors.

Preferably, the capacitive transistors are formed so that the first portions of the gates of the capacitive transistors extend in depth in the substrate and are spaced apart from each other by a distance comprised between 0.1 μm and 1.5 μm.

In an advantageous implementation, said manufacture of said at least one capacitive transistor further comprises forming two dielectric strips extending: either completely over lateral borders of the second portion of its gate, or over the lateral borders of the second portion of its gate and over the semiconductor substrate.

Advantageously, the method further comprises forming at least one planar transistor including: forming a drain and a source of said at least one planar transistor in the semiconductor substrate; forming a floating gate of said at least one planar transistor extending over the semiconductor substrate and being of the same nature as the gate of said at least one capacitive transistor; forming a control gate extending over the floating gate and over the semiconductor substrate between the drain and the source; forming a first dielectric layer extending between the floating gate and the semiconductor substrate, and being of the same nature as the dielectric layer of said at least one capacitive transistor which extends between the gate of this capacitive transistor and the semiconductor substrate; and forming a second dielectric layer extending between the floating gate and the control gate.

### BRIEF DESCRIPTION OF THE DRAWINGS

Further advantages and features of the invention will become apparent on studying the detailed description of embodiments, which are in no way restrictive, and the appended drawings wherein:

FIG. 1 illustrates a sectional view of an embodiment of an integrated circuit;

FIG. 2 illustrates a top view of the integrated circuit of FIG. 1;

FIG. 3 illustrates a top view of a variant of the integrated circuit;

FIG. 4 illustrates an embodiment of an integrated circuit comprising a semiconductor substrate and several capacitive transistors; and

FIGS. 5A-5G illustrate steps in an implementation of a method for manufacturing an integrated circuit as shown in FIG. 1.

### DETAILED DESCRIPTION

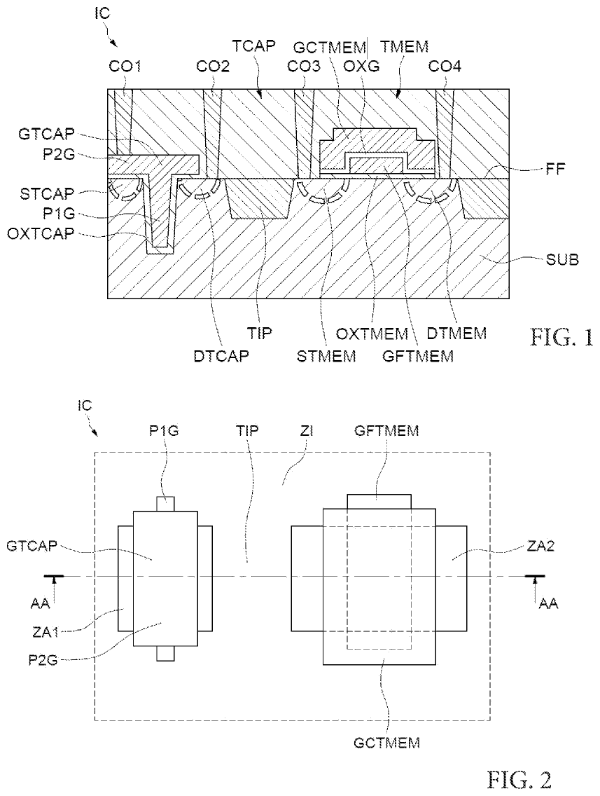

FIG. 1 illustrates a sectional view of an embodiment of an integrated circuit IC. FIG. 2 illustrates a top view of such an integrated circuit IC. The view of FIG. 1 is made according to the section AA represented in FIG. 2. The circuit IC comprises a semiconductor substrate SUB and at least one capacitive transistor TCAP. The capacitive transistor TCAP is adapted to operate at high voltage. For example, the capacitive transistor TCAP is configured to operate at a voltage higher than 7V in particular comprised between 7V and 15V. The capacitive transistor TCAP including a source STCAP, a drain DTCAP and a gate GTCAP.

The source STCAP and the drain DTCAP are formed in an active area ZA1 of the semiconductor substrate SUB. For example, the source STCAP and the drain DTCAP are formed in a well configured for operation at high voltage. The well has a first conductivity type, in particular P type. This active area ZA1 is surrounded by an isolation area ZI including shallow isolation trenches TIP (also referred to by those skilled in the art as Shallow Trench Isolation (STI)). The gate GTCAP is formed by a monolithic layer having a first portion P1G and a second portion P2G. In particular, the gate GTCAP is formed by a polysilicon layer. For example, the polysilicon layer is a 1,500 Angström (Å) (i.e., 150 nanometers (nm)) “Poly1” type one. The gate GTCAP has a second conductivity type, in particular N type.

The first portion P1G of the gate extends in depth in the semiconductor substrate SUB between the source STCAP and the drain DTCAP of the capacitive transistor TCAP.

The second portion P2G of the gate extends at the surface of the semiconductor substrate SUB from the first portion P1G of the gate GTCAP. The first and second portions P1G, P2G are made of a unitary body of conductive material (for example, doped polysilicon). It will be noted that a part of the first portion P1G of the gate GTCAP extends (in a first direction perpendicular to a second direction extending between source and drain—the second direction corresponding to the direction noted by AA) beyond an outer perimeter of the second portion P2G of the gate GTCAP.

The capacitive transistor TCAP also comprises a dielectric layer OXTCAP extending between the gate GTCAP and the semiconductor substrate SUB. Thus, the dielectric layer extends between the semiconductor substrate SUB and the first portion P1G of the gate GTCAP.

The dielectric layer OXTCAP also extends over the face FF of the semiconductor substrate SUB between the second portion P2G of the gate GTCAP and the semiconductor substrate SUB. The dielectric layer OXTCAP is configured to support operation at high voltage, for example comprised between 7V and 15V in particular in the range of 15 Volts. The dielectric layer OXTCAP may be made of silicon dioxide. The dielectric layer may have a thickness comprised between 80 Ångström (i.e., 8 nm) and 400 Ångström (i.e., 40 nm).

The integrated circuit IC also comprises a first contact CO1 connected to the gate GTCAP of the capacitive transistor TCAP. The integrated circuit IC also comprises a second contact CO2 connected to the source STCAP or to the drain DTCAP of the capacitive transistor TCAP (in the figure illustrated connected to the drain DTCAP).

Thus, the capacitive transistor TCAP is configured to operate as a capacitive element. In particular, the gate GTCAP of the capacitive transistor TCAP is used as a first terminal of the capacitive element. Furthermore, the drain DTCAP, the source STCAP and the semiconductor substrate SUB (“bulk”) are connected together so as to be used as a second terminal of the capacitive element.

More particularly, the capacitive transistor TCAP has a surface capacitive value which depends on the length for which its first portion P1G extends in depth in the semiconductor substrate SUB.

Thus, the deeper the first portion P1G of the gate GTCAP extends, the more its surface capacitive value increases.

This first portion P1G extends in the active area ZA1 of the substrate and extends over the isolation area ZI formed in the substrate around said active area ZA1.

In particular, in order to avoid coupling with the elements of the integrated circuit located nearby, it is preferable to have first portions P1G of the capacitive transistor TCAP having longitudinal parts extending at different depths depending on whether these parts extend in the active area ZA1 or in the isolation area ZI. For example, the part of the first portion P1G that extends in the active area ZA1 may extend in depth in the substrate SUB over a distance comprised between 700 nm and 900 nm. Each part of the first portion P1G that extends in the isolation area ZI may extend in depth in the substrate SUB over a distance comprised between 900 nm and 1,200 nm.

Such a capacitive transistor TCAP may have a surface capacitive value comprised between 4 fF/μm² and 12 fF/μm².

Because the surface capacitive value of such a capacitive transistor TCAP is greater, it is possible to reduce the size of the capacitive transistors so as to reduce the area of the integrated circuit used for high-voltage operation.

For example, the use of such capacitive transistors TCAP instead of planar capacitive transistors allows reducing by 30% to 50% the surface of the area for high voltage. Thus, it is possible to manufacture more integrated circuits starting from the same semiconductor disk (“wafer”), and therefore reduce the manufacturing cost of each integrated circuit.

Moreover, such a capacitive transistor TCAP has the advantage of enabling a positioning of the contact CO1 directly on its gate GTCAP, and not on a shallow isolation trench outside an active area of the capacitive transistor.

The integrated circuit IC may also comprise a planar transistor TMEM. In particular, this planar transistor TMEM may be used as a data storage element in a non-volatile memory. Such a planar transistor TMEM includes a source STMEM, a drain DTMEM and a gate region GTMEM.

The drain DTMEM and the source STMEM of the planar transistor TMEM are formed in an active area ZA2 of the semiconductor substrate SUB. This active area ZA2 is surrounded by the isolation layer ZI.

The gate region GTMEM of the planar transistor TMEM extends at the surface of the semiconductor substrate SUB between its drain DTMEM and its source STMEM. The gate region GTMEM of the planar transistor TMEM comprises a floating gate GFTMEM and a control gate GCTMEM.

The floating gate GFTMEM extends over a first dielectric layer OXTMEM formed over the semiconductor substrate SUB. The floating gate GFTMEM is formed by a polysilicon layer having the same characteristics as the gate GTCAP of the capacitive transistor TCAP. For example, the polysilicon layer is a 1,500 Angström (Å) (i.e., 150 nm) “Poly1” type one.

The control gate GCTMEM is separated from the floating gate GFTMEM by a second dielectric layer OXGC. The second dielectric layer OXGC may be an oxide-nitride-oxide (“ONO”) layer.

The control gate GCTMEM is formed by a second polysilicon layer extending above the floating gate GFTMEM and above the semiconductor substrate SUB between the source STMEM and the drain of the transistor DTMEM. For example, the polysilicon layer is a 1,500 Ångström (Å) (i.e., 150 nm) “Poly2” type one.

It will be noted that a portion of the floating gate GFTMEM extends (in the first direction perpendicular to the second direction extending between source and drain—the second direction corresponding to the direction noted by AA) beyond an outer perimeter of the control gate GCTMEM.

The circuit also comprises a contact (not represented) connected to the control gate GCTMEM, a contact CO3 connected to the source of the transistor TMEM and a contact CO4 connected to the drain of the transistor TMEM.

In such an integrated circuit, the capacitive transistor TCAP may be manufactured using manufacturing steps common with those of the planar transistor TMEM, as will be described hereinafter.

FIG. 3 illustrates a top view of a variant of the previously-described integrated circuit IC. In this variant, the capacitive transistor TCAP further comprises two dielectric strips S_ONO extending over lateral borders of the second portion P2G of its gate GTCAP and over the semiconductor substrate SUB.

Alternatively, it is possible to provide for a capacitive transistor TCAP comprising two dielectric strips S_ONO completely extending over lateral borders of the second portion P2G of its gate GTCAP.

These two dielectric strips S_ONO may be made of an oxide-nitride-oxide (“ONO”). These two dielectric strips S_ONO allow avoiding electrical short-circuits.

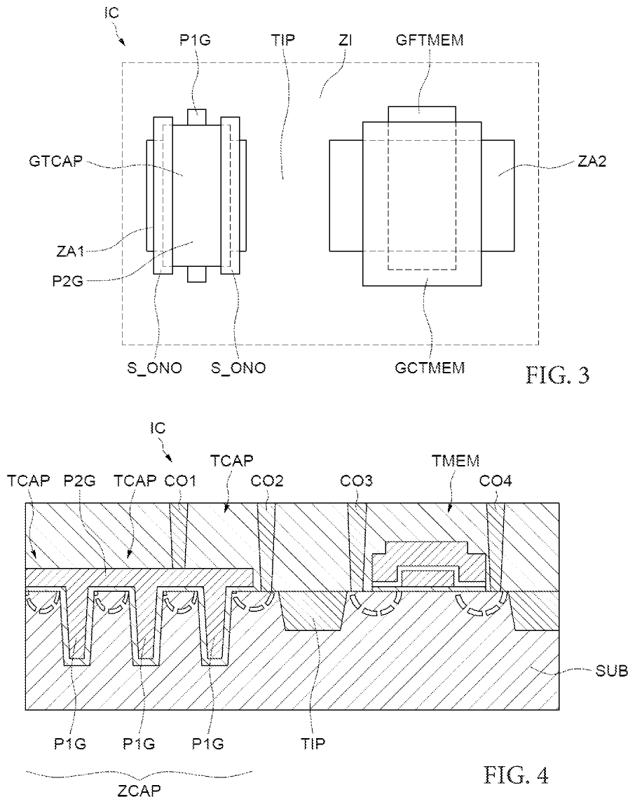

FIG. 4 illustrates an embodiment of an integrated circuit IC comprising a semiconductor substrate SUB and several capacitive transistors TCAP. These capacitive transistors TCAP are located in an area ZCAP of the integrated circuit IC intended to receive these capacitive transistors TCAP.

This area ZCAP of the integrated circuit IC is separated by shallow isolation trenches TIP from the other areas of the integrated circuit IC, including in particular at least one transistor TMEM. In particular, in FIG. 4, three capacitive transistors TCAP are represented.

These capacitive transistors TCAP are connected together so as to increase their capacitive value as a whole. In particular, the gates GTCAP of the capacitive transistors TCAP are formed by the same polysilicon layer.

This polysilicon layer is identical to (i.e., of the same nature as) the polysilicon layer of the previously-described planar transistor TMEM.

The first portions of the gates GTCAP of the transistors TCAP may be spaced apart from each other by a distance comprised between 100 nm and 300 nm.

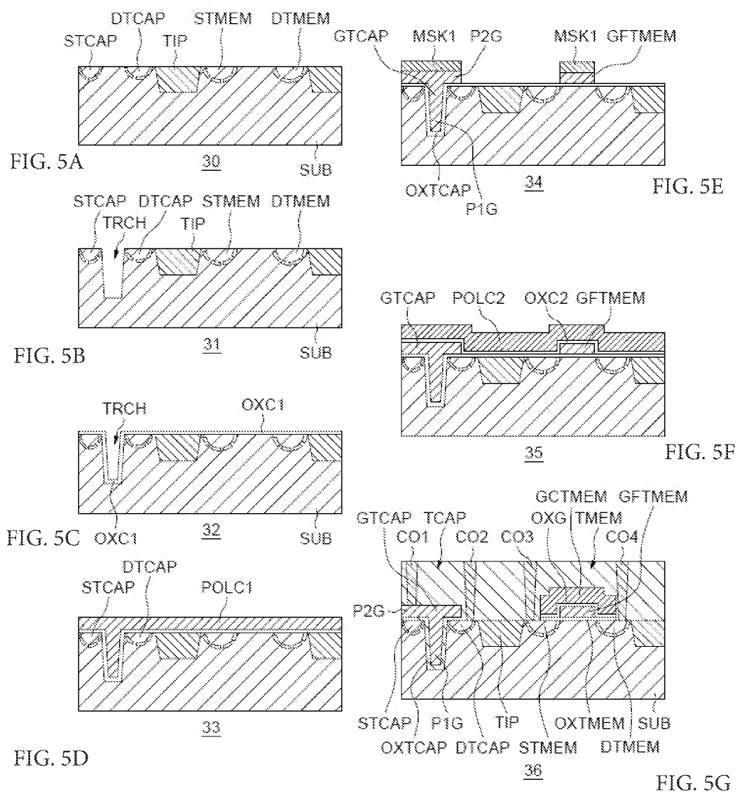

FIGS. 5A-5G illustrate steps in an implementation of a method for manufacturing an integrated circuit IC as described before with reference to FIG. 1.

FIG. 5A: The method comprises obtaining a semiconductor substrate SUB. The method also comprises forming shallow isolation trenches TIP. The method also comprises forming the drain DTCAP and the source STCAP of the capacitive transistor TCAP and forming the drain DTMEM and the source STMEM of the planar transistor TMEM. The sectional view 30 of the integrated circuit illustrates the result of these steps of the method.

FIG. 5B: The method comprises etching a trench TRCH in the semiconductor substrate SUB between the source STCAP and the drain DTCAP of the capacitive transistor TCAP. The trench is etched over a depth comprised between 300 nm and 1,200 nm. The sectional view 31 of the integrated circuit illustrates the result of this step of the method.

FIG. 5C: Afterwards, the method comprises forming a dielectric layer OXC1 over the semiconductor substrate SUB. Thus, the dielectric layer OXC1 is formed at the surface of the semiconductor substrate SUB in the trench TRCH and over its face FF. The dielectric layer OXC1 may be formed by oxidation of the surface of the semiconductor substrate SUB. The sectional view 32 of the integrated circuit illustrates the result of this step of the method.

FIG. 5D: Afterwards, the method comprises a deposition of a polysilicon layer POLC1 over the semiconductor substrate SUB. The sectional view 33 of the integrated circuit illustrates the result of this step of the method.

FIG. 5E: Afterwards, the method comprises a photolithography step. During this step, a mask MSK1 made of resin is formed over the first polysilicon layer. The mask MSK1 made of resin has openings.

Thus, some portions of the first polysilicon layer are covered by the resin and other portions are not. Afterwards, the portions of the first polysilicon layer POLC1 not covered by the mask are removed.

In particular, the mask is configured to cover the first polysilicon layer POLC1 at the capacitive transistor TCAP and of the planar transistor TMEM. Hence, this step allows delimiting the gate GTCAP of the capacitive transistor TCAP and the floating gate GFTMEM of the planar transistor TMEM. Afterwards, the resin of the mask MSK is removed. The sectional view 34 of the integrated circuit illustrates the result of this step of the method.

FIG. 5F: Afterwards, the method comprises forming a second dielectric layer OXC2, in particular an oxide-nitride-oxide (“ONO”) layer. Afterwards, a second polysilicon layer is deposited over the second dielectric layer POLC2. The sectional view 35 of the integrated circuit illustrates the result of this step of the method.

FIG. 5G: Afterwards, the method comprises a photolithography step. In this step, a mask made of resin is formed over the second polysilicon layer POLC2. The mask made of resin has openings.

Thus, some portions of the second polysilicon layer POLC2 are covered by the resin and other portions are not. Afterwards, the portions of the second polysilicon layer POLC2 not covered by the mask are removed.

In particular, the mask is configured to cover the second polysilicon layer POLC2 at the planar transistor TMEM. Hence, this step allows delimiting the control gate GCMEM of the planar transistor TMEM.

The method also includes forming contacts. In particular, a contact CO1 is formed so as to be connected to the gate GTCAP of the capacitive transistor TCAP, a contact CO2 is formed so as to be connected to the source STCAP or to the drain DTCAP of the capacitive transistor TCAP. A contact (not represented) is formed so as to be connected to the control gate of the planar transistor TMEM, a contact CO3 is formed so as to be connected to the source STMEM of the planar transistor TMEM, a contact CO4 is formed so as to be connected to the drain DTMEM of the planar transistor TMEM.

The sectional view 36 of the integrated circuit illustrates the result of these steps of the method.

Such a method uses the same dielectric layer OXC1 and the same polysilicon layer POLC1 to respectively form the dielectric layers OXTCAP and OXTEM of the transistors TCAP and TMEM, and the polysilicon layers of the gate GTCAP and of the floating gate GFTMEM of the transistors TCAP and TMEM.

Thus, the formation of the capacitive transistor TCAP has the advantage of including manufacturing steps common with the formation of the planar transistor TMEM. In particular, the floating gate GFTMEM of the planar transistor TMEM, and the gate GTCAP (in particular the portions P1G and P2G) are manufactured simultaneously. The formation of the capacitive transistor TCAP requires only one additional manufacturing step to form the trench TRCH compared to the manufacture of the planar transistor TMEM. Thus, the formation of the capacitive transistor TCAP is inexpensive.

Moreover, the manufacture of the capacitive transistor may also comprise forming two dielectric strips S_ONO extending either completely over lateral borders of the second portion P2G of its gate GTCAP, or over the lateral borders of the second portion P2G of its gate GTCAP and over the semiconductor substrate SUB.

1. An integrated circuit, comprising:
a semiconductor substrate;
at least one capacitive transistor supported by said semiconductor substrate and including:
a drain and a source disposed in the semiconductor substrate;
a gate having a first portion extending in depth in the semiconductor substrate, and a second portion prolonging said first portion and extending over the semiconductor substrate; and
a dielectric layer extending between the gate and the semiconductor substrate.

2. The integrated circuit according to claim 1, wherein the first portion of the gate of said at least one capacitive transistor extends in depth in the substrate over a distance comprised between 300 nanometers and 1,200 nanometers.

3. The integrated circuit according to claim 2, wherein the first portion of the gate of said at least one capacitive transistor has a width comprised between 100 nanometers and 300 nanometers.

4. The integrated circuit according to claim 3, wherein the second portion of the gate of said at least one capacitive transistor has a thickness comprised between 100 nanometers and 200 nanometers.

5. The integrated circuit according to claim 1, wherein the dielectric layer of said at least one capacitive transistor is an oxide layer.

6. The integrated circuit according to claim 1, wherein the dielectric layer of said at least one capacitive transistor has a thickness comprised between 8 nanometers and 40 nanometers.

7. The integrated circuit according to claim 1, further comprising a first contact connected to the second portion of the gate of said at least one capacitive transistor and a second contact connected to the source or to the drain of said at least one capacitive transistor.

8. The integrated circuit according to claim 1, wherein the gate of said at least one capacitive transistor is made of polysilicon.

9. The integrated circuit according to claim 1, comprising several capacitive transistors, the second portion of the gate of capacitive transistor being common for said several capacitive transistors.

10. The integrated circuit according to claim 9, wherein the first portions of the gates of the several capacitive transistors extend in depth in the substrate and are spaced apart from each other by a distance comprised between 0.1 micrometers and 1.5 micrometers.

11. The integrated circuit according to claim 1, wherein said at least one capacitive transistor further comprises two dielectric strips extending completely over lateral borders of the second portion of the gate.

12. The integrated circuit according to claim 1, wherein said at least one capacitive transistor further comprises two dielectric strips extending over lateral borders of the second portion of the gate and over the semiconductor substrate.

13. The integrated circuit according to claim 1, further comprising at least one planar transistor including:
a drain and a source disposed in the semiconductor substrate;
a floating gate extending over the semiconductor substrate and having a same thickness as the second portion of the gate of said at least one capacitive transistor;
a control gate over the floating gate and extending adjacent side edges of the control gate and over the drain and the source in the semiconductor substrate;
a first dielectric layer extending between the floating gate and the semiconductor substrate, and being of a same nature as the dielectric layer of said at least one capacitive transistor which extends between the gate of the capacitive transistor and the semiconductor substrate; and
a second dielectric layer extending between the floating gate and the control gate.

14. The integrated circuit according to claim 13, wherein a portion of floating gate extends beyond an outer perimeter of the control gate.

15. The integrated circuit according to claim 1, wherein a part of the first portion of the gate of the capacitive transistor extends beyond an outer perimeter of the second portion of the gate of the capacitive transistor.

16. A method for manufacturing an integrated circuit, comprising:
manufacturing at least one capacitive transistor over a semiconductor substrate;
wherein manufacturing said at least one capacitive transistor comprises:
forming a drain and a source of said at least one capacitive transistor in the semiconductor substrate;
forming a gate of said at least one transistor comprising etching a trench in the semiconductor substrate then depositing an electrically-conductive layer so that the gate has a first portion of said conductive layer extending in depth in said trench etched in the semiconductor substrate, and a second portion of said conductive layer prolonging said first portion and extending over the semiconductor substrate; and
forming a dielectric layer in said trench so that the dielectric layer extends between the gate and the semiconductor substrate.

17. The method according to claim 16, wherein the trench has a depth comprised between 300 nanometers and 1,200 nanometers.

18. The method according to claim 17, wherein the trench has a width comprised between 100 nanometers and 300 nanometers.

19. The method according claim 18, wherein the second portion of the gate of said at least one capacitive transistor has a thickness comprised between 100 nanometers and 200 nanometers.

20. The method according to claim 16, wherein the dielectric layer of said at least one capacitive transistor is an oxide layer.

21. The method according to claim 16, wherein the dielectric layer of said at least one capacitive transistor has a thickness comprised between 8 nanometers and 40 nanometers.

22. The method according to claim 16, further comprising forming a first contact connected to the second portion of the gate of said at least one capacitive transistor and forming a second contact connected to the source or to the drain of the capacitive transistor.

23. The method according to claim 16, wherein the gate of said at least one capacitive transistor is made of polysilicon.

24. The method according to claim 16, comprising forming several capacitive transistors, the second portion of the gate of these capacitive transistors being common for these capacitive transistors.

25. The method according to claim 24, wherein the capacitive transistors are formed so that the first portions of the gates of the capacitive transistors extend in depth in the substrate and are spaced apart from each other by a distance comprised between 0.1 micrometers and 1.5 micrometers.

26. The method according to claim 25, further comprising forming two dielectric strips extending completely over lateral borders of the second portion of the gate.

27. The method according to claim 25, further comprising forming two dielectric strips extending over lateral borders of the second portion of the gate and over the semiconductor substrate.

28. The method according to claim 16, further comprising forming at least one planar transistor including:
forming a drain and a source of said at least one planar transistor in the semiconductor substrate;
forming a floating gate of said at least one planar transistor extending over the semiconductor substrate and being of the same nature as the gate of said at least one capacitive transistor;
forming a control gate extending over the floating gate and over the semiconductor substrate between the drain and the source;
forming a first dielectric layer extending between the floating gate and the semiconductor substrate, and being of the same nature as the dielectric layer of said at least one capacitive transistor which extends between the gate of this capacitive transistor and the semiconductor substrate; and
forming a second dielectric layer extending between the floating gate and the control gate.
